(19) United States
(12) Patent Application Publication
(10) Pub. No.: US 2026/0096111 A1
(43) Pub. Date: Apr. 2, 2026

(54) CAPACITOR, MEMORY DEVICE, AND MANUFACTURING METHOD THEREOF

(71) Applicant: Samsung Electronics Co., Ltd., Suwon-si (KR)

(72) Inventors: Kyooho JUNG, Suwon-si (KR); Donghyun KIM, Suwon-si (KR); Sangjun LEE, Suwon-si (KR); Jooho LEE, Suwon-si (KR); Duk Hyun CHOE, Suwon-si (KR)

(73) Assignee: Samsung Electronics Co., Ltd., Suwon-si (KR)

(21) Appl. No.: 19/212,179

(22) Filed: May 19, 2025

(30) Foreign Application Priority Data
Sep. 30, 2024 (KR) 10-2024-0133278

(51) Int. Cl. H10D 1/68; H10B 12/00

(52) U.S. Cl. CPC H10D 1/696; H10B 12/315; H10B 12/318; H10D 1/716; H10B 12/033; H10D 1/714

(57) ABSTRACT

According to at least one embodiment of the present disclosure, there is provided a capacitor including a lower electrode, an upper electrode, a dielectric layer disposed between the lower electrode and the upper electrode, and a lower interface layer disposed between the lower electrode and the dielectric layer, the dielectric layer includes a ferroelectric, and the lower interface layer includes an oxide of one or more tetravalent atoms and an oxide of one or more pentavalent atoms and the content of the pentavalent atoms relative to the total number of elements excluding oxygen among constituent elements of the lower interface layer is 3 at % to 20 at %.

### CROSS-REFERENCE TO RELATED APPLICATION

This application claims priority to Korean Patent Application No. 10-2024-0133278 filed on Sep. 30, 2024 and all the benefits accruing therefrom under 35 U.S.C. § 119, the contents of which are incorporated by reference in their entirety.

### BACKGROUND

The present disclosure relates to a capacitor, a memory device, and a manufacturing method thereof.

In dynamic random-access memory (DRAM) devices, a unit device may have a structure including one transistor and one capacitor. To achieve a higher integration of DRAM devices, capacitors having relatively high electrostatic capacitance and low leakage current are being explored.

### SUMMARY

The present disclosure is provided to improve the phenomenon of deterioration of remnant polarization (Pᵣ) characteristics of a ferroelectric when a thickness of a ferroelectric layer in a capacitor having a metal-ferroelectric-metal (MFM) structure decreases below a specific range.

The effects of present disclosure are not limited to those mentioned above, and other effects not mentioned will be clearly understood by those skilled in the art from the following description.

According to at least one embodiment of the present disclosure, a capacitor includes a lower electrode, an upper electrode, a dielectric layer insulating the lower electrode from the upper electrode, the dielectric layer including a ferroelectric, and a lower interface layer between the lower electrode and the dielectric layer, the lower interface layer including an oxide of one or more tetravalent atoms and an oxide of one or more pentavalent atoms and a content of the pentavalent atoms relative to the total number of elements excluding oxygen among constituent elements of the lower interface layer is in a range of 3 atomic percent (at %) to 20 at %.

According to at least one embodiment of the present disclosure, a capacitor includes a lower electrode, an upper electrode, a dielectric layer insulating the lower electrode from the upper electrode, the dielectric layer including a ferroelectric and a crystal structure having an orthorhombic crystal system, and a lower interface layer between the lower electrode and the dielectric layer, the lower interface layer including an oxide of one or more tetravalent atoms and an oxide of one or more pentavalent atoms,, wherein the crystal structure having the orthorhombic crystal system has a predominate orientation of (110)o or (020)o with respect to an in-plane direction of an interface between the lower interface layer and the dielectric layer.

According to still another embodiment of the present disclosure, a memory device includes at least one of the capacitor in accordance with the example embodiment of the present disclosure and one or more transistors electrically connected to the at least one capacitor.

Details of other embodiments are included in the Detailed Description and drawings.

### BRIEF DESCRIPTION OF THE DRAWINGS

The drawings shown in the present disclosure are according to embodiments, and ratios of the width, height or thickness of each component is for describing the present disclosure in detail, and the ratio may be different from the actual ones. In addition, each component illustrated in the drawings may be exaggerated to describe the present disclosure in detail. In addition, in a coordinate system shown in the drawing, each axis may can be perpendicular to the others, a direction pointed by an arrow may be a + direction, and a direction opposite to the direction pointed by the arrow (a direction rotated by 180 degrees) may be a − direction:

FIG. 1 schematically illustrates at least a portion of a capacitor according to at least one embodiment of the present disclosure;

FIG. 2 is an enlarged view of part P in FIG. 1;

FIG. 3 schematically illustrates at least a portion of the capacitor according to at least one embodiment of the present disclosure;

FIG. 4 is an enlarged view of part Q in FIG. 3;

FIGS. 5A to 11 are views for describing a method of manufacturing a capacitor according to some embodiments of the present disclosure;

FIG. 12 schematically illustrates at least a portion of a memory device according to at least one embodiment of the present disclosure;

FIG. 13 schematically illustrates at least a portion of the memory device according to at least one embodiment of the present disclosure;

FIG. 14 is a set of cross-sectional views taken along lines A-A′ and B-B′ in FIG. 13;

FIG. 15 schematically illustrates at least a portion of a memory device according to at least one embodiment of the present disclosure;

FIG. 16 schematically illustrates at least a portion of the memory device according to at least one embodiment of the present disclosure;

FIG. 17 is a graph showing remnant polarization (Pᵣ) characteristics according to the Ta content of a lower interface layer in a dielectric layer of a capacitor according to an embodiment of the present disclosure;

FIG. 18 is a graph showing a hysteresis curve according to the Ta content of the lower interface layer in the dielectric layer of the capacitor according to the embodiment of the present disclosure;

FIG. 19 shows a graph of an X-ray diffraction (XRD) spectrum in a vertical direction (in-plane) of an interface between the lower interface layer of the dielectric layer and the dielectric layer according to at least one embodiment of the present disclosure; and

FIG. 20 shows a graph of an X-ray diffraction (XRD) spectrum in the vertical direction (in-plane) of the interface between the lower interface layer of the dielectric layer and the dielectric layer according to at least one embodiment of the present disclosure.

### DETAILED DESCRIPTION OF EMBODIMENTS

Prior to the detailed description of the present disclosure, it should be noted that terms or words used in the present specification and claims should not be construed as being limited to their usual or dictionary meanings. Rather, the terms or words should be interpreted to have a meaning or concept that is consistent with the technical idea of the present disclosure based on the principle that the inventors are capable of appropriately defining the concept of the term to best describe their disclosure. Embodiments described in the present specification and configurations illustrated in the drawings are merely some example embodiments of the present disclosure and may not represent all of the technical ideas of the present disclosure. Accordingly, there may be various equivalents and variations capable of replacing the embodiments or configurations at the time of filing of the present disclosure.

Expressions such as upper side, upper portion, lower side, lower portion, side surface, front surface, and rear surface hereinafter are represented based on a direction illustrated in a drawing and may be represented otherwise when the direction of a corresponding object changes. In other words, such spatially relative terms are intended to encompass different orientations of the device in use or operation in addition to the orientation depicted in the figures, and that the device may be otherwise oriented (rotated 90 degrees or at other orientations) and the spatially relative terms used herein interpreted accordingly. The shape or size of elements in drawings may be exaggerated for clearer description. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, when referring to being in a range of “C to D”, this means C inclusive to D inclusive unless otherwise specified.

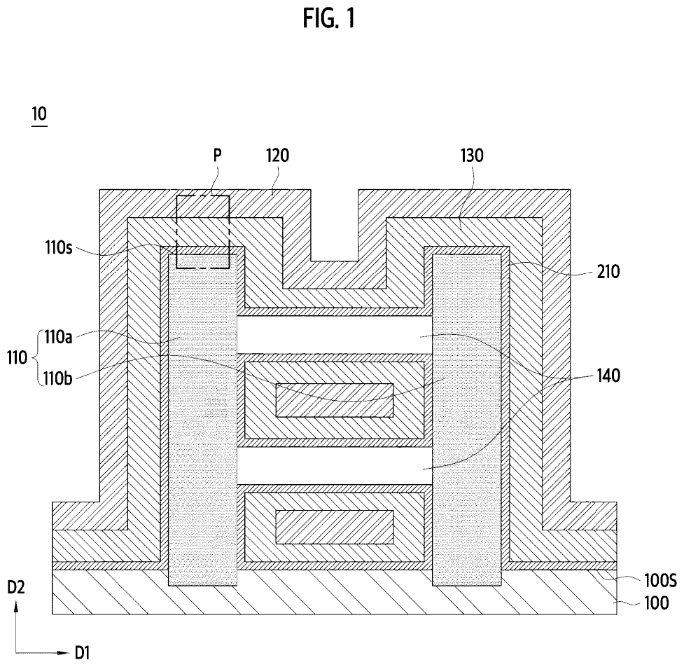

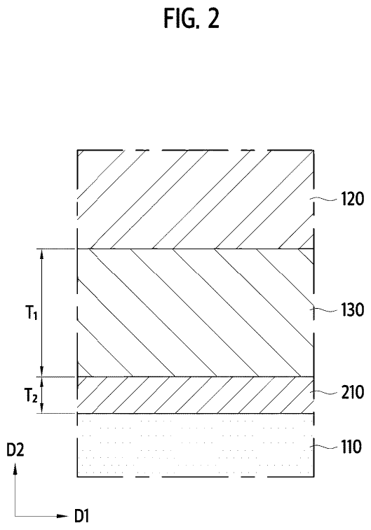

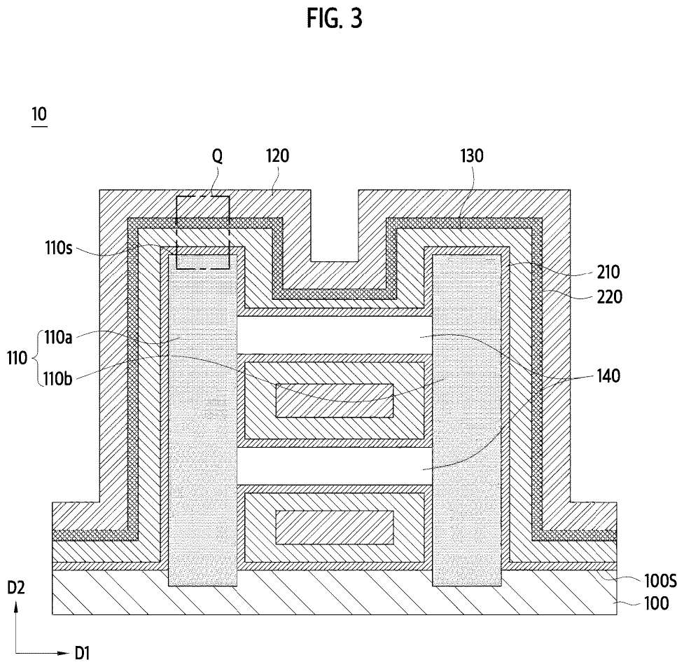

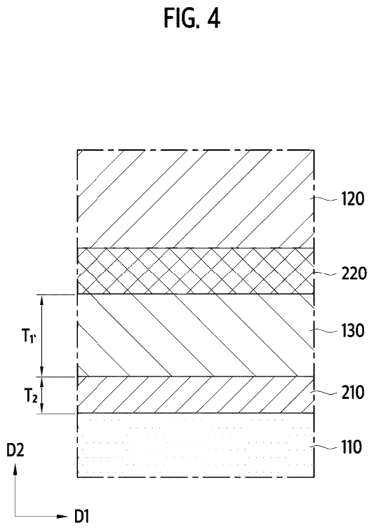

FIG. 1 schematically illustrates at least a portion of a capacitor 10 according to at least one embodiment of the present disclosure. FIG. 2 is an enlarged view of part P in FIG. 1. FIG. 3 schematically illustrates at least a portion of the capacitor 10 according to at least one embodiment of the present disclosure. FIG. 4 is an enlarged view of part Q in FIG. 3.

The capacitor 10 according to the embodiment of the present disclosure may include a substrate structure 100, a lower electrode 110, an upper electrode 120, a dielectric layer 130, and a lower interface layer 210.

The capacitor 10 according to at least one embodiment of the present disclosure may be included in, for example, a memory device. In at least one example, the memory device may include the capacitor 10 and may include one or more transistors. Here, the transistors (not illustrated) may be electrically connected to the capacitor 10. For example, the transistors may be electrically connected to one of the lower electrode 110 or the upper electrode 120. In at least one embodiment, the memory device may be a volatile memory device. The volatile memory device may be, for example, a dynamic RAM (DRAM). The DRAM may be, for example, a three-dimensional DRAM. In one example, the memory device may be a memory device including a vertical channel transistor (VCT). In at least one example, the memory device may be a DRAM having a vertical stacked structure.

The substrate structure 100 may be and/or include a substrate. The substrate may be, for example, one or more of a semiconductor (e.g., an elemental and/or compound semiconductor) substrate, a plastic substrate, a glass substrate, a ceramic substrate, a silicon-on-insulator (SOI) substrate, and/or the like. In at least one example, the capacitor 10 including the lower electrode 110, the upper electrode 120, and the dielectric layer 130 may be disposed on a surface 100S of the substrate structure.

The substrate structure 100 according to some embodiments may include, although not separately illustrated, an impurity region due to doping, a peripheral circuit configured to select and/or control an electronic element (such as a transistor, a memory cell, etc.), and/or the like.

In at least one example, the lower electrode 110 may be extended to be long in a vertical direction (e.g., the second direction D2) relative to the surface 100S of the substrate. For example, in at least one example, the lower electrode 110 may have a length extending in the second direction D2 greater than a width along a horizontal direction (e.g., the first direction D1 perpendicular to the second direction D2). In at least one example, the lower electrode 110 may have, for example, a pillar shape.

In at least one example, the lower electrode 110 may include a conductor, such as a zero-band gap material and/or a material with an equivalent conductivity (e.g., 10⁵ S/m or more, and/or 10⁶ S/m or more when measured at room temperature). For example, the conductor may be (or include) one or more of a doped semiconductor material, a conductive metal nitride (e.g., titanium nitride, tantalum nitride, niobium nitride, or tungsten nitride), a conductive metal oxynitride (e.g., titanium oxynitride, tantalum oxynitride, niobium oxynitride, or tungsten oxynitride), a metal (e.g., ruthenium, iridium, titanium, or tantalum), a conductive metal oxide (e.g., iridium oxide or niobium oxide), and/or the like. In at least one example, the lower electrode 110 may include one or more of titanium nitride (TiN), niobium nitride (NbN), and/or molybdenum nitride (MoN). In at least one example, the lower electrode 110 may include titanium nitride (TiN).

The lower electrode may include a first lower electrode 110a and a second lower electrode 110b. In at least one example, the first lower electrode 110a and the second lower electrode 110b may be spaced apart from each other, e.g., in the first direction D1.

The capacitor 10 may include a supporter 140 between the first lower electrode 110a and the second lower electrode 110b. The supporter 140 may be connected to the first lower electrode 110a and the second lower electrode 110b. In at least one example, the supporter 140 may support the first lower electrode 110a and the second lower electrode 110b by connecting the first lower electrode 110a and the second lower electrode 110b. In at least one example, the supporter 140 may be included in a support structure including one or more supporters 140. In FIG. 1, two supporters 140 are illustrated, but this is only for convenience of description and the examples are not limited thereto. When there are two or more supporters 140, a length of each supporter 140 extended in the second direction D2 may be the same as or different from the other, and each supporter 140 may be spaced apart from the other (for example, in the second direction D2). In at least one example, the supporter 140 may be disposed parallel to the first direction D1 to stably support the first lower electrode 110a and the second lower electrode 110b.

In at least one example, an upper surface of the supporter 140 may be disposed to be lower in the second direction D2 than at least one of an upper surface of the first lower electrode 110a and an upper surface of the second lower electrode 110b. Specifically, the upper surface of the supporter 140 may be closer to the surface 100S of the substrate structure in the second direction D2 than at least one of the upper surface of the first lower electrode 110a and the upper surface of the second lower electrode 110b. In at least one example, the upper surface of the supporter 140 may be disposed at the same position as at least one of the upper surface of the first lower electrode 110a and the upper surface of the second lower electrode 110b in the second direction D2.

In at least one example, the supporter 140 may include an insulator, such as one or more of silicon nitride (SiN), silicon carbonitride (SiCN), silicon boron nitride (SiBN), silicon carbonate (SiCO), silicon oxynitride (SiON), silicon oxide (SiO), silicon oxycarbonitride (SiOCN), and/or the like. In at least one example, the supporter 140 may include silicon nitride (SiN).

The upper electrode 120 may be spaced apart from the first lower electrode 110a and the second lower electrode 110b with the dielectric layer 130 therebetween. The upper electrode 120 is illustrated as a single film, but is not limited thereto. For example, the upper electrode 120 may be a multilayer film.

In at least one example, the upper electrode 120 may include a conductor, for example, one or more of a doped semiconductor material, a conductive metal nitride (e.g., titanium nitride, tantalum nitride, niobium nitride, or tungsten nitride), a conductive metal oxynitride (e.g., titanium oxynitride, tantalum oxynitride, niobium oxynitride, or tungsten oxynitride), a metal (e.g., ruthenium, iridium, titanium, or tantalum), a conductive metal oxide (e.g., iridium oxide or niobium oxide), and/or the like. In at least one example, the upper electrode 120 may include one or more of titanium nitride (TiN), niobium nitride (NbN), and/or molybdenum nitride (MoN). In at least one example, the upper electrode 120 may include titanium nitride (TiN).

The dielectric layer 130 may be disposed between the lower electrode 110 and the upper electrode 120. In at least one example, the dielectric layer 130 may be formed on at least a portion of the lower electrode 110. In at least one example, the dielectric layer 130 may be formed on at least a portion of the supporter 140.

In at least some examples, the dielectric layer 130 may be spaced apart from the lower electrode 110 (refer to FIGS. 1 and 2) and/or from the upper electrode 120 (refer to FIGS. 3 and 4). In at least one example, a lower interface layer 210 may be disposed between the dielectric layer 130 and the lower electrode 110; and/or an upper interface layer 220 may be disposed between the dielectric layer 130 and the upper electrode 120. In at least one example, the lower interface layer 210 may include an oxide of one or more tetravalent atoms and an oxide of one or more pentavalent atoms.

In the present specification, the one or more tetravalent atoms may include one or more of elements of Group 4 and/or elements of Group 14 of the periodic table. For example, the one or more tetravalent atoms may include one or more of titanium (Ti), zirconium (Zr), hafnium (Hf), silicon (Si), germanium (Ge), and/or tin (Sn). In at least one example, the one or more tetravalent atoms may include one or more of titanium (Ti), zirconium (Zr), and/or hafnium (Hf).

In the present specification, the one or more pentavalent atoms may include one or more of elements of Group 5 and/or elements of Group 15 of the Periodic Table. For example, the one or more pentavalent atoms may include one or more of tantalum (Ta), niobium (Nb), and/or vanadium (V). In at least one example, the one or more pentavalent atoms may include one or more of tantalum (Ta) and/or niobium (Nb).

In at least one embodiment, the upper interface layer 220 may be disposed between the upper electrode 120 and the dielectric layer 130. In at least one example, the upper interface layer 220 may include a second oxide of one or more tetravalent atoms and a second oxide of one or more pentavalent atoms. In at least one example, the second oxide of one or more tetravalent atoms included in the upper interface layer 220 may be the same as (and/or substantially similar to) the oxide of one or more tetravalent atoms included in the lower interface layer 210, and the second oxide of one or more pentavalent atoms included in the upper interface layer 220 may be the same as (and/or substantially similar to) the oxide of one or more pentavalent atoms included in the lower interface layer 210, but the example embodiments are not limited thereto. In at least one embodiment, the second oxide of one or more tetravalent atoms and/or the second oxide of one or more pentavalent atoms in the upper interface layer 220 may be different from the oxide of one or more tetravalent atoms and/or the oxide of one or more pentavalent atoms, respectively. In at least one example, the dielectric layer 130 may be spaced apart from the supporter 140. In at least one example, a supporter interface layer (not illustrated) may be disposed between the dielectric layer 130 and the supporter 140.

In at least one example, the dielectric layer 130 may include an insulator. For example, the dielectric layer 130 may include, but is not limited to, one or more of silicon oxide, silicon nitride, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and/or the like. The dielectric layer 130 is illustrated as a single film, but is not limited thereto and may be a multilayer film.

In at least one example, the dielectric layer 130 may include a ferroelectric. In at least one example, a ferroelectric may have spontaneous polarization characteristics due to application of an electric field, and may have remnant polarization Pᵣ, which allows polarization characteristics to remain even in the absence of the electric field after spontaneous polarization. In at least one example, the remnant polarization (Pᵣ) characteristics may refer to the polarization characteristics that remains after the electric field is removed after spontaneous polarization due to the application of an electric field.

In at least one example, the ferroelectric may comprise a material having a ferroelectric phase (e.g., a crystal structure lacking an inversion center (e.g., is non-centrosymmetric)) as a primary phase. In at least some embodiments, the material of the ferroelectric may include a compound including one or more of hafnium (Hf) and/or zirconium (Zr) and having ferroelectric properties. In at least one example, the ferroelectric may be an oxide including one or more selected from the group consisting of hafnium (Hf) and zirconium (Zr). In at least one example, the ferroelectric may include hafnium oxide (HfO) (that is a compound including hafnium (Hf)), zirconium oxide (ZrO) (that is a compound including zirconium (Zr)), and/or hafnium-zirconium oxide (HZO) (that is a compound including hafnium (Hf) and zirconium (Zr)). However, the ferroelectric is not limited to the compounds described above and may include, for example, one or more of BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, GeTe, LiTaO₃, KNaNbO₃, BaSrTiO₃, HF0·5Zr0·5O₂, PbZrₓTi₁₋ₓO₃ (0<x<1), Ba(Sr, Ti)O₃, Bi₄-xLaₓTi₃O₁₂ (0<x<1), SrBi₂Ta₂O₉, Pb₅Ge₅O₁₁, SrBi₂Nb₂O₉, YMnO₃, and/or the like having a ferroelectric phase. In at least one example, the ferroelectric may include an orthorhombic crystal system. In at least one example, the ferroelectric may include a compound doped with an impurity, and the impurity may include one or more of carbon (C), silicon (Si), magnesium (Mg), aluminum (Al), yttrium (Y), nitrogen (N), germanium (Ge), tin (Sn), gadolinium (Gd), lanthanum (La), scandium (Sc), and/or strontium (Sr).

In at least one example, the dielectric layer 130 may include a crystal structure having a predominate orientation of (110) or (020) with respect to a vertical direction (in-plane) of the interface between the lower interface layer 210 and the dielectric layer 130. For example, referring to FIG. 2, the dielectric layer 130 may include a crystal structure having the predominate orientation of (110) or (020) with respect to the in-plane direction along the second direction D2 of the interface between the lower interface layer 210 and the dielectric layer 130. In at least one example, the dielectric layer 130 may include a crystal structure having an orthorhombic crystal system (which is a non-centrosymmetric system). In at least one example, the crystal structure having the orthorhombic crystal system may have the predominate orientation of (110) or (020) with respect to the vertical direction (in-plane) of the interface between the lower interface layer 210 and the dielectric layer 130. Here, the dielectric layer 130 may include a crystal structure having a predominate orientation of (110)o or (020)o with respect to the vertical direction, and the subscript of the Miller index may refer to the orthorhombic crystal system. In at least one example, the dielectric layer 130 may include a crystal structure having an orthorhombic crystal system and a crystal structure having a tetragonal crystal system, and in this case, the crystal structure having the orthorhombic crystal system may be more numerous (e.g., more dominant) than the crystal structure having the tetragonal crystal system. In at least one example, the properties of the crystal structure of the dielectric layer 130 may be measured through X-ray diffraction (XRD) analysis.

In at least one example, the crystal structure having the predominate orientation of (110) or (020) with respect to the vertical direction of the interface between the lower interface layer 210 included in the dielectric layer 130 and the dielectric layer 130 may mainly exist at an interface adjacent to the lower interface layer 210, and in the crystal structure, the predominate orientation may be determined during a process of forming the dielectric layer 130.

In at least one example, the dielectric layer 130 may include the ferroelectric and have the crystal structure having a predominate orientation of (110)o with respect to the vertical direction of the interface between the lower interface layer 210 and the dielectric layer 130, and the oxide of one or more pentavalent atoms included in the lower interface layer 210 may include tantalum (Ta).

In at least one example, the dielectric layer 130 may include the ferroelectric and have the crystal structure having a predominate orientation of (020)o with respect to the vertical direction of the interface between the lower interface layer 210 and the dielectric layer 130, and the oxide of one or more pentavalent atoms included in the lower interface layer 210 may include niobium (Nb).

In at least one example, a thickness T₁ of the dielectric layer 130 may be 7 nm or less, 6.9 nm or less, 6.8 nm or less, 6.7 nm or less, 6.6 nm or less, 6.5 nm or less, 6.4 nm or less, 6.3 nm or less, 6.2 nm or less, 6.1 nm or less, 6 nm or less, 5.9 nm or less, 5.8 nm or less, 5.7 nm or less, 5.6 nm or less, 5.5 nm or less, 5.4 nm or less, 5.3 nm or less, 5.2 nm or less, 5.1 nm or less, and/or 5 nm or less. In at least one example, when the thickness T₁ of the dielectric layer 130 satisfies the above-described range, the size of the capacitor 10 may be reduced (or minimized) to improve the integration density of the memory device. However, when the thickness T₁ of the dielectric layer 130 satisfies the above-described range, the dielectric layer 130 including the ferroelectric may include a crystal structure having a tetragonal (e.g., a centrosymmetric) crystal system that weakens residual polarization characteristics. However, the weakening of the polarization characteristics may be reduced (or minimized) by the combination of the lower interface layer 210 and the upper interface layer 220. In at least one example, referring to FIG. 2, the thickness T₁ of the dielectric layer 130 may mean the length along the second direction D2.

In at least one example, the content of one or more pentavalent atoms relative to the total number of elements, excluding oxygen, among the constituent elements of the lower interface layer 210 may be 3 atomic percent (at %) to 20 at %, 4 at % to 19 at %, 5 at % to 18 at %, 6 at % to 17 at %, 7 at % to 16 at %, and/or 8 at % to 15 at %. By setting the composition of the lower interface layer 210 in this way, the dielectric layer 130 may reduce and/or minimize weakening of the polarization characteristics.

In at least one example, a thickness T₂ of the lower interface layer 210 may be 2 nm or less, 1.9 nm or less, 1.8 or less, 1.7 or less, 1.6 or less, 1.5 nm or less, 1.4 or less, 1.3 or less, 1.2 or less, 1.1 or less, and/or 1 nm or less. The thickness T₂ of the lower interface layer 210 may be 0.1 nm or more. In at least one example, referring to FIG. 2, the thickness T₂ of the lower interface layer 210 may mean the length along the second direction D2 at an upper surface of the lower interface layer 210. In at least one example, the ratio (T₁/T₂) of the thickness T₁ of the dielectric layer 130 to the thickness T₂ of the lower interface layer 210 may be 1 or more, greater than 1, 1.5 or more, 2 or more, 3 or more, 4 or more, and/or 5 or more, and/or 20 or less, 18 or less, 16 or less, 14 or less, 12 or less, and/or 10 or less.

In at least one example, the lower interface layer 210 disposed between the lower electrode 110 and the dielectric layer 130 may include a metal element included in the lower electrode 110 that is diffused through heat treatment from the lower electrode 110 to the dielectric layer 130 during the process of manufacturing the capacitor 10.

In at least one example, the lower interface layer 210 may be disposed between the supporter 140 and the dielectric layer 130. In at least one example, the lower interface layer 210 disposed between the supporter 140 and the dielectric layer 130 may have a different composition from the lower interface layer 210 disposed between the lower electrode 110 and the dielectric layer 130. In at least one example, the lower interface layer 210 disposed between the supporter 140 and the dielectric layer 130 may not include the metal element included in the lower electrode 110 that is diffused through heat treatment during the process of manufacturing the capacitor 10. In at least one example, “not include” may mean “not substantially include” (e.g., is not detectable or is within a standard of error for the detection) In at least one example, “not include the metal element included in the lower electrode 110” may mean that the metal element included in the lower electrode 110 is not intentionally diffused through heat treatment during the process of manufacturing the capacitor. In at least one example, the lower interface layer 210 disposed between the supporter 140 and the dielectric layer 130 may include a metal element that is not derived from the lower electrode 110, but identical to the metal element included in the lower electrode 110.

The capacitor 10 according to some embodiments of the present disclosure may include an oxide layer (not illustrated) disposed between the lower interface layer 210 and the lower electrode 110. In at least one example, the oxide layer may be additionally disposed between the lower interface layer 210 and the dielectric layer 130. In at least one example, the oxide layer may include the metal element included in the lower electrode 110. In at least one example, the oxide layer may be formed by a metal element of the lower electrode 110 bonding with oxygen atoms. In at least one example, the oxygen atoms bonding with the metal element of the lower electrode 110 may be derived from ozone O₃, but are not limited thereto. In at least one example, the thickness of the oxide layer may be 0.1 nm or less.

In at least one example, the content of one or more pentavalent atoms relative to the total number of elements, excluding oxygen, among the constituent elements of the upper interface layer 220 may be 3 at % to 20 at %, 4 at % to 19 at %, 5 at % to 18 at %, 6 at % to 17 at %, 7 at % to 16 at %, or 8 at % to 15 at %. By setting the composition of the upper interface layer 220 in this way, the dielectric layer 130 may reduce and/or minimize weakening of the polarization characteristics.

In at least one example, the thickness of the upper interface layer 220 may be 2 nm or less, 1.9 nm or less, 1.8 nm or less, 1.7 nm or less, 1.6 nm or less, 1.5 nm or less, 1.4 nm or less, 1.3 nm or less, 1.2 nm or less, 1.1 nm or less, and/or 1 nm or less.

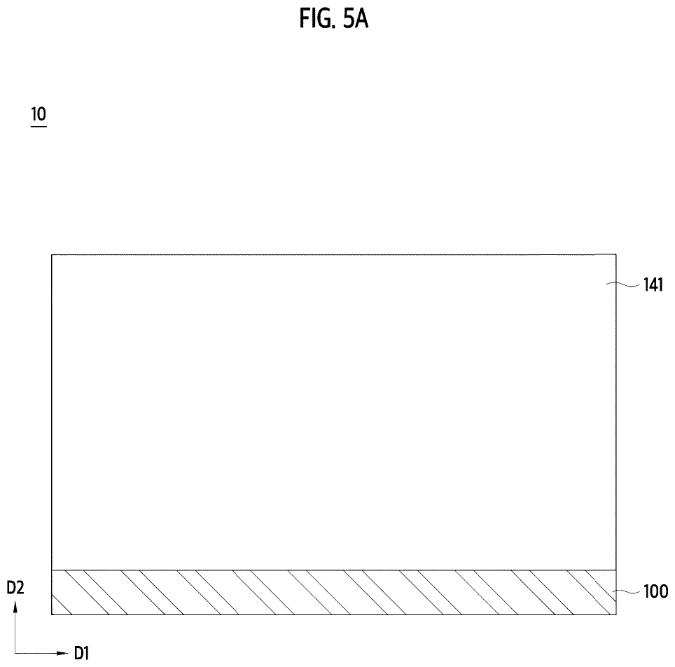

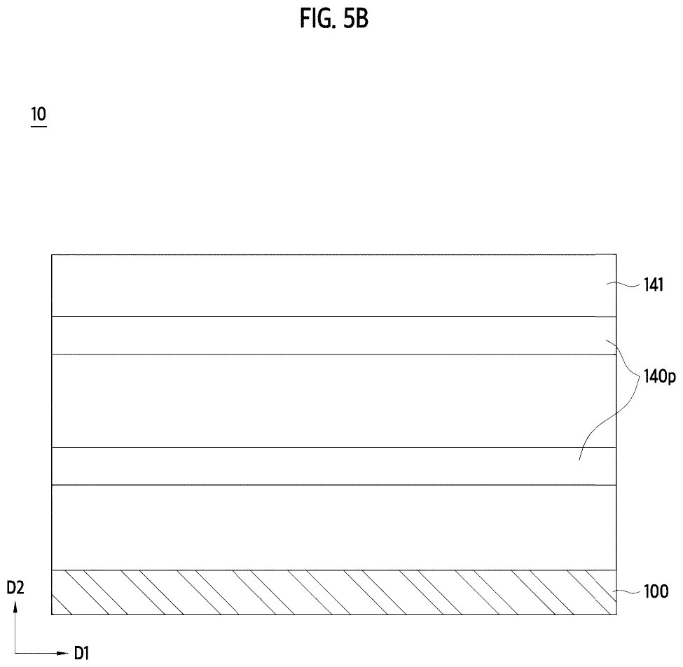

FIG. 5A is a view for describing a method of manufacturing a capacitor 10 according to at least one embodiment of the present disclosure. FIG. 5B is a view for describing a method of manufacturing a capacitor 10 according to another embodiment of the present disclosure. Unlike FIG. 5A, FIG. 5B is a view for describing a method of manufacturing a capacitor 10 including a supporter 140.

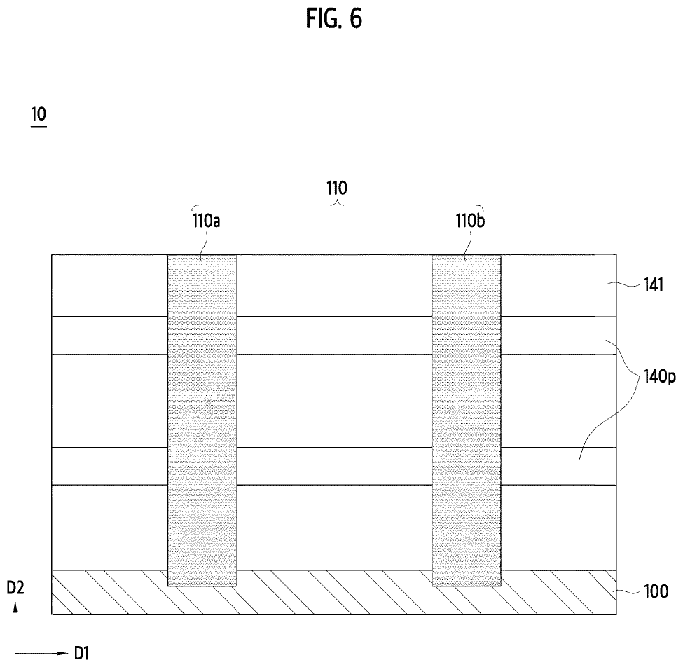

FIGS. 6 to 11 are views for describing a method of manufacturing a capacitor 10 according to at least one embodiment of the present disclosure. Hereinafter, the description of the method of manufacturing a capacitor 10 may refer to the above-described contents described through FIGS. 1 to 4 unless contradictory.

Referring to FIG. 5A, in at least one example, the method of manufacturing a capacitor 10 may include forming a mold film 141 on a substrate structure 100. Referring to FIG. 5B, in at least one example, the method of manufacturing a capacitor 10 may include forming a supporter film 140p and a mold film 141 on a substrate structure 100. There may be one or two or more supporter films 140p, and in the case of two or more, each supporter film 140p may be formed to be spaced apart from the other in a second direction D2 with the mold film 141 interposed therebetween. Hereinafter, a description is given based on the method of manufacturing the capacitor 10 including the supporter 140, but this is only for convenience of description and the examples are not limited thereto. For example, in at least one embodiment, the method of manufacturing the capacitor may result in a capacitor including at least one lower electrode 110a and/or 110b, at least one of the lower and/or upper interface layers 210 and/or 220, a dielectric layer 130, and an upper electrode 120, but without the supporters 140.

Referring to FIG. 6, in at least one example, the method of manufacturing a capacitor 10 may include forming a lower electrode 110 passing through the supporter film 140p and the mold film 141. For example, the forming the lower electrode 110 may include forming a hole in a stack including the supporter film 140p and the mold film 141, and filling the hole with a conductor. In at least one example, the supporter film 140p and the mold film 141 may be in contact with a portion of side walls of the first lower electrode 110a and the second lower electrode 110b. In at least one example, the lower electrode 110 may include a first lower electrode 110a and a second lower electrode 110b. In at least one example, the first lower electrode 110a and the second lower electrode 110b may be formed to extend to be long in the second direction D2. In at least one example, each of the first lower electrode 110a and the second lower electrode 110b may be formed to have, for example, a pillar-shaped shape.

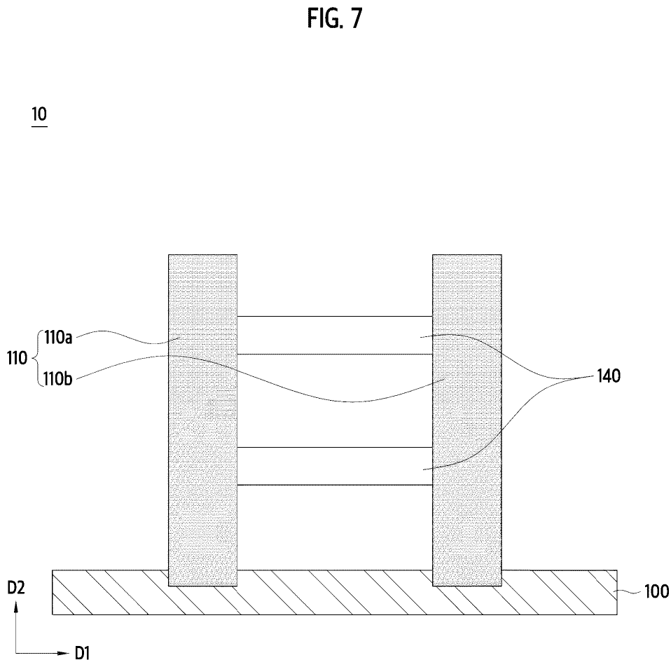

Referring to FIG. 7, in at least one example, the method of manufacturing a capacitor 10 may include removing the mold film 141. In at least some embodiments, the removing the mold film 141 may further include removing at least a portion of the supporter film 140p. A remainder of the supporter film 140p may form the supporter 140 connecting adjacent lower electrodes 110a and 110b. In at least some embodiments, there may be zero, one, two, or more supporters 140, and in the case of two or more, each supporter 140 may be formed to be spaced apart from the other in the second direction D2. In at least one example, the mold film 141 may be removed from a region excluding the first lower electrode 110a, the second lower electrode 110b, and the supporter 140 connecting the first lower electrode 110a and the second lower electrode 110b. The mold film 141 may be removed, for example, through an etching process. In this way, the supporter 140 connecting adjacent lower electrodes 110a and 110b may be formed, and an empty space may be formed between the first lower electrode 110a, the second lower electrode 110b, and the supporter 140.

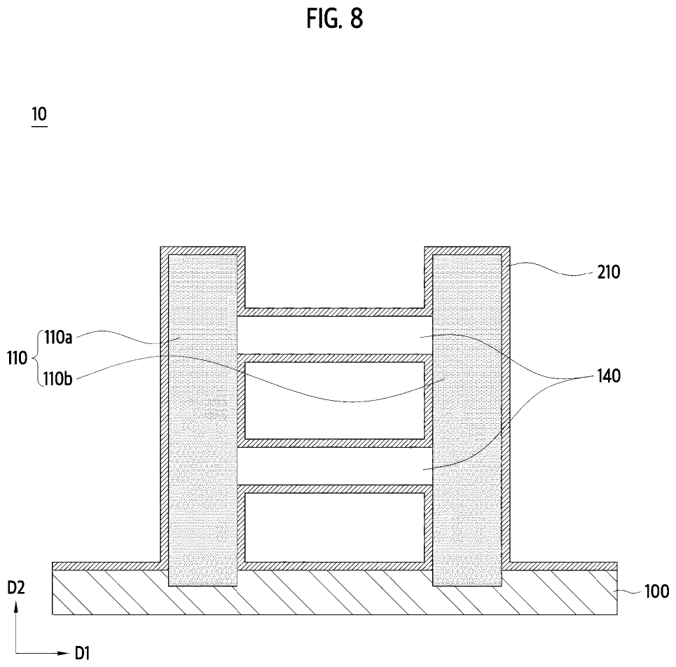

Referring to FIG. 8, in at least one example, the method of manufacturing a capacitor 10 may include forming a lower interface layer 210 on the first lower electrode 110a and the second lower electrode 110b. In at least one example, the lower interface layer 210 may be formed to surround at least a portion of each of the first lower electrode 110a and the second lower electrode 110b. In at least one example, the method of manufacturing a capacitor 10 may include forming the lower interface layer 210 on the supporter 140. In at least one example, the lower interface layer 210 may be formed to surround at least a portion of the supporter 140. That is, in at least one example, the method of manufacturing a capacitor may include forming the lower interface layer 210 that surrounds at least a portion of each of the first lower electrode 110a and the second lower electrode 110b and a supporter interface layer that surrounds at least a portion of the supporter 140. In at least one example, the lower interface layer 210 may be formed through deposition. In the present specification, deposition may be performed through various methods such as chemical vapor deposition (CVD), physical vapor deposition (PVD), atomic layer deposition (ALD), or the like. In at least one example, the lower interface layer 210 may optionally be formed through atomic layer deposition. In at least one example, the components of the capacitor 10 may be formed, for example, through deposition, unless otherwise specified, but are not limited thereto.

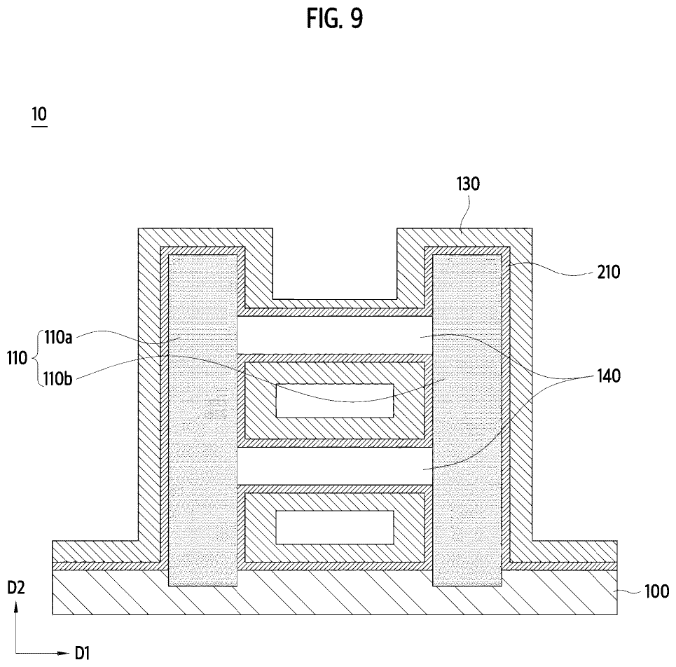

Referring to FIG. 9, in at least one example, the method of manufacturing a capacitor 10 may include forming a dielectric layer 130 on the lower interface layer 210. In at least one example, the dielectric layer 130 may be formed to surround at least a portion of each of the lower interface layer 210 and the supporter interface layer. In at least one example, the dielectric layer 130 may be formed along a profile of the lower interface layer 210.

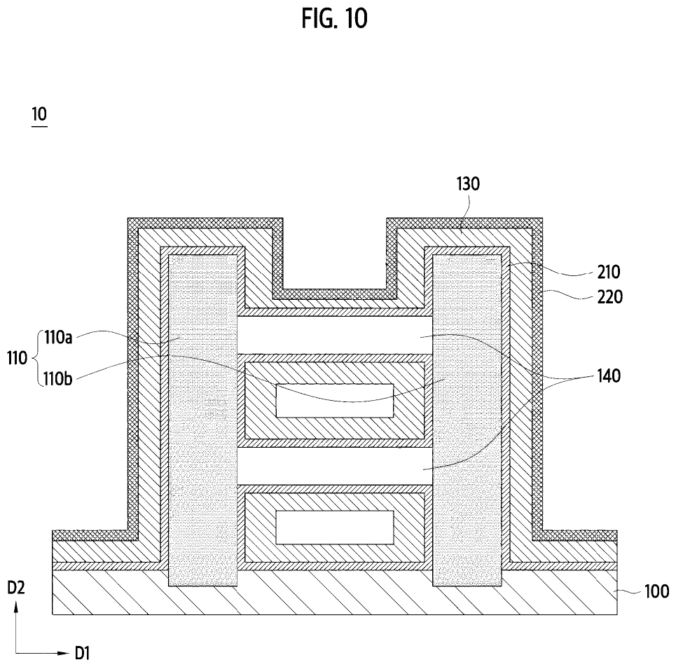

Referring to FIG. 10, in at least one example, the method of manufacturing a capacitor 10 may include forming an upper interface layer 220 on the dielectric layer 130. In at least one example, the upper interface layer 220 may be formed along a profile of the dielectric layer 130. However, the examples are not limited thereto, and in at least some embodiments, the upper interface layer 220 may be omitted (refer to FIGS. 1 and 2).

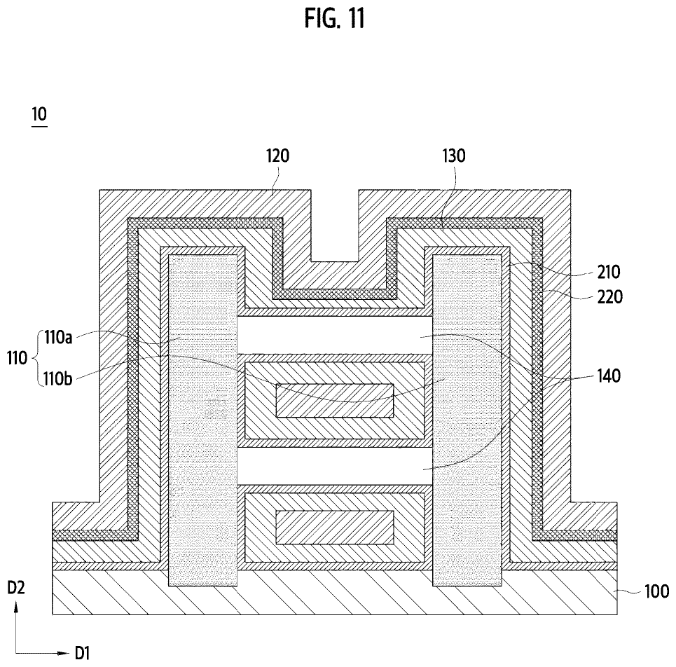

Referring to FIG. 11, in at least one example, the method of manufacturing a capacitor 10 may include forming an upper electrode 120 on the upper interface layer 220. In at least one example, the upper electrode 120 may be formed along the profile of the upper interface layer 220.

The method of manufacturing a capacitor 10 according to at least one embodiment of the present disclosure may include a heat treatment process. In at least one example, a metal element included in the lower electrode 110 may diffuse into the lower interface layer 210 through the heat treatment process. In at least one example, the dielectric layer 130 including a ferroelectric may be crystallized through the heat treatment process. In at least one example, the heat treatment process is maintained at, 500° C. or higher, 550° C. or higher, 600° C. or higher, 650° C. or higher, and/or 700° C. or higher, but the examples are not limited thereto.

In at least one example, the heat treatment process may be performed before forming the dielectric layer 130 to so that the metal element included in the lower electrode 110 may diffuse into the lower interface layer 210.

In at least one example, the heat treatment process may be performed after the dielectric layer 130 is formed so that the metal element included in the lower electrode 110 diffuses into the lower interface layer 210 and the dielectric layer 130 including the ferroelectric is crystallized. In at least one example, the heat treatment process may be performed after forming the upper electrode 120. In at least one example, the heat treatment process is performed after the dielectric layer 130 is formed to crystallize the dielectric layer 130 including the ferroelectric.

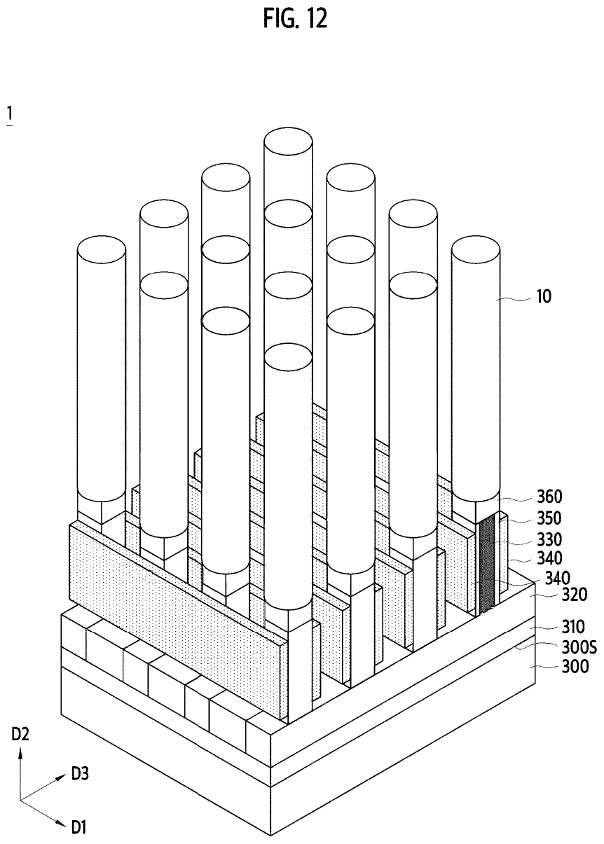

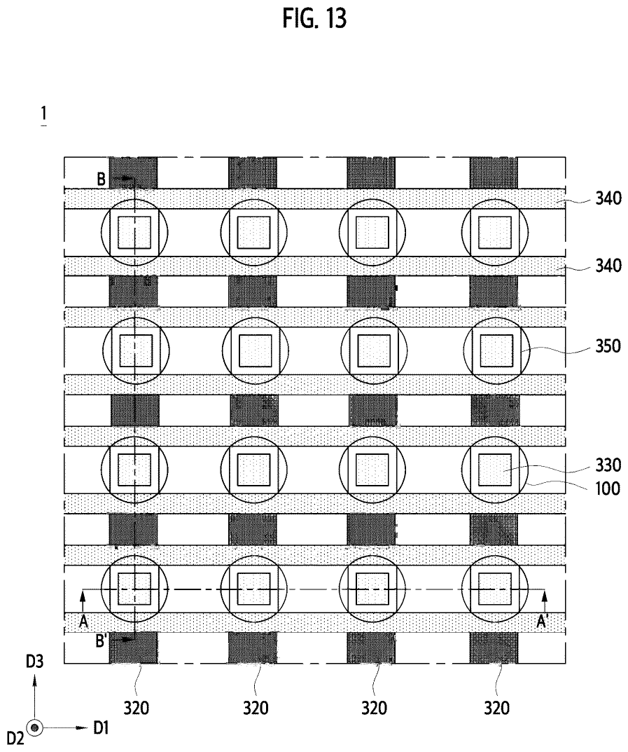

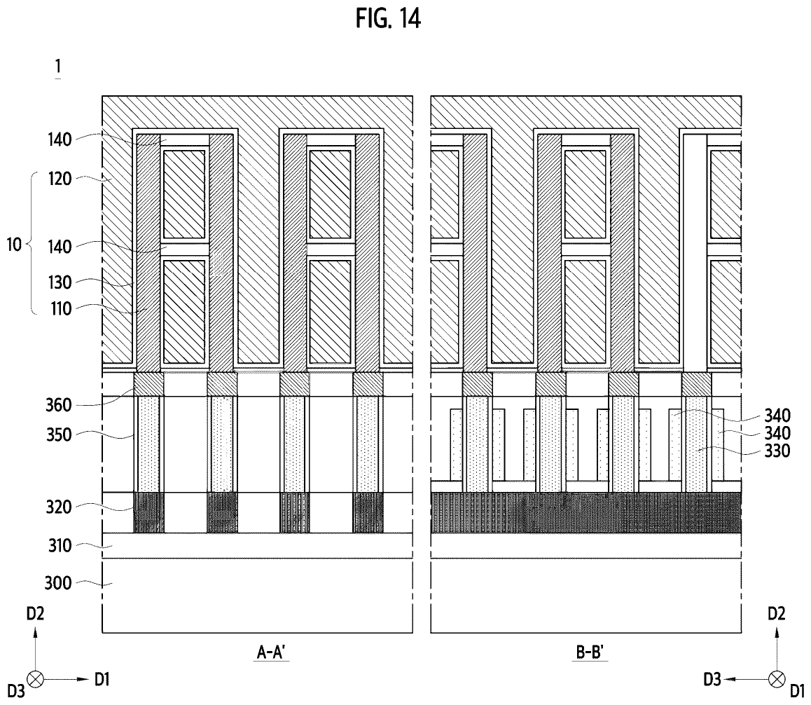

FIG. 12 schematically illustrates at least a portion of a memory device 1 according to at least one embodiment of the present disclosure. FIG. 13 schematically illustrates at least a portion of the memory device 1 according to at least one embodiment of the present disclosure. FIG. 14 is a set of cross-sectional views taken along lines A-A′ and B-B′ in FIG. 13.

In at least one example, the memory device 1 may include a substrate 300, a conductive line 320, a channel layer 330, a gate electrode 340, a gate insulating layer 350, a capacitor contact 360, and a capacitor 10. In at least one example, the memory device 1 may include a vertical channel transistor (VCT). In at least one example, the vertical channel transistor may refer to a transistor having a structure in which the channel layer 330 extends from a surface of the substrate 300 in a vertical direction (that is, a second direction D2).

The capacitor 10 of FIGS. 12 to 14 may refer to the description of the capacitor 10 in FIGS. 1 to 13, unless otherwise contradictory. FIG. 12 omits the supporters 140 and the upper electrode 150 for clarity. Meanwhile, the substrate 300 may refer to the contents of the aforementioned substrate structure 100 unless otherwise contradictory.

In at least one example, an insulating layer 310 may be disposed on the substrate 300. In the present specification, the insulating layer 310 may include an insulator (e.g., a material having an electrical conductivity of 10⁻⁶ S/m or less),. In the present specification, the insulating material may include, for example, one or more of silicon oxide, silicon nitride, silicon oxynitride, and/or the like. In at least one example, a plurality of conductive lines 320 may be spaced apart from each other in the first direction D1 and extended in the third direction D3 on the insulating layer 310. In at least one example, the space between the plurality of conductive lines 320 may be filled with an insulating material. In at least one example, the plurality of conductive lines 320 may function as bit lines of the memory device 1.

In at least one example, the plurality of conductive lines 320 may include a conductor, such as one or more of doped polysilicon, a metal, a conductive metal nitride, a conductive metal silicide, a conductive metal oxide, and/or the like. For example, the plurality of conductive lines 320 may be formed of one or more of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, and/or the like. In at least one example, the plurality of conductive lines 320 may include a single layer or multiple layers of the materials described above. In at least one example, the plurality of conductive lines 320 may include a two-dimensional conductor and/or a two-dimensional semiconductor material, for example, the two-dimensional material may include one or more of graphene, carbon nanotubes, and/or the like.

In at least one example, the channel layers 330 may be disposed in a matrix form to be spaced apart from each other in the first direction D1 and the third direction D3 on the plurality of conductive lines 320. In at least one example, the channel layer 330 may have a first width along the first direction D1 and a first height along the second direction D2, and the first height may be greater than the first width. For example, the first height may be about 2 to 10 times the first width, but is not limited thereto. In at least one example, a lower portion of the channel layer 330 may function as a first source/drain region (not illustrated), and an upper portion of the channel layer 330 may function as a second source/drain region (not illustrated). In at least one example, a portion of the channel layer 330 between the first source/drain region and the second source/drain region may function as a channel region (not shown) through which electrons or holes move.

In at least one example, the channel layer 330 may include an oxide semiconductor. In at least one example, the channel layer may include, for example, the oxide semiconductor InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. In at least one example, the channel layer 330 may include a single layer or multiple layers of the oxide semiconductor. In at least one example, the channel layer 330 may have a band gap energy greater than the band gap energy of silicon. In at least one example, the channel layer 330 may have a band gap energy of about 1.5 eV to 5.6 eV or a band gap energy of about 2.0 eV to 4.0 eV. In at least one example, the channel layer 330 may be crystalline, and in another example, the channel layer 330 may be amorphous, but is not limited thereto. In at least one example, the channel layer 330 may include a two-dimensional semiconductor material, for example, the two-dimensional semiconductor material may include one or more of MoS₂, doped graphene, carbon nanotubes, and/or the like.

In at least one example, the gate electrode 340 may extend in the first direction D1 on both sidewalls of the channel layer 330. In at least one example, the gate electrode 340 may include a conductor, such as one or more of doped polysilicon, a metal, a conductive metal nitride, a conductive metal silicide, a conductive metal oxide, and/or the like. For example, the gate electrode 340 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, and/or a combination thereof, but is not limited thereto.

In at least one example, the gate insulating layer 350 may surround at least a portion of a sidewall of the channel layer 330, and may be interposed between the channel layer 330 and the gate electrode 340. In at least one example, the entire sidewall of the channel layer 330 may be surrounded by the gate insulating layer 350, and a portion of the sidewall of the gate electrode 340 may be in contact with the gate insulating layer 350.

In at least one example, the gate insulating layer 350 may extend in an extension direction of the gate electrode 340 (that is, the first direction D1), and only two of sidewalls of the channel layer 330 facing the gate electrode 340 may be in contact with the gate insulating layer 350.

In at least one example, the gate insulating layer 350 may be formed of an insulator film, such as one or more of a silicon oxide film, a silicon oxynitride film, a high-k dielectric film having a higher dielectric constant than the silicon oxide film, or a combination thereof. In at least one example, the high-k dielectric film may be formed of a metal oxide or a metal oxynitride. In at least one example, the high-k dielectric film usable as the gate insulating layer 350 may be formed of one or more of HfO₂, HfSiO, HfSiON, HfTaO, HfTiO, HfZrO, ZrO₂, Al₂O₃, and/or the like.

In at least one example, the capacitor contact 360 may be disposed on the channel layer 330. The capacitor contacts 360 may be disposed to overlap the channel layer 330 when viewed in the second direction D2 and arranged in a matrix form to be spaced apart from each other in the first direction D1 and the third direction D3. In at least one example, the capacitor contact 360 may be formed of a conductor, such as one or more of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, and/or the like.

In at least one example, the capacitor 10 may be disposed on the capacitor contact 360. In at least one example, the capacitor 10 may include a lower electrode 110, a dielectric layer 130, and an upper electrode 120.

In at least one example, the lower electrode 110 may be electrically connected to the upper surface of the capacitor contact 360. The lower electrode 110 may be formed in a pillar type that extends in the second direction D2, but is not limited thereto. In at least one example, the lower electrode 110 may be disposed to overlap the capacitor contact 360 when viewed in the second direction D2 and arranged in a matrix form to be spaced apart from each other in the first direction D1 and the third direction D3. Alternatively, a landing pad (not illustrated) may be further disposed between the capacitor contact 360 and the lower electrode 110 so that the lower electrode 110 is arranged in a hexagonal shape.

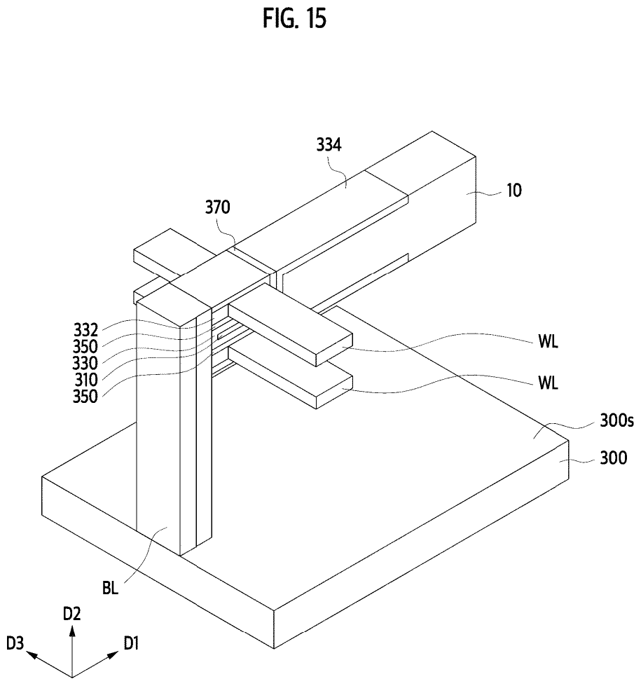

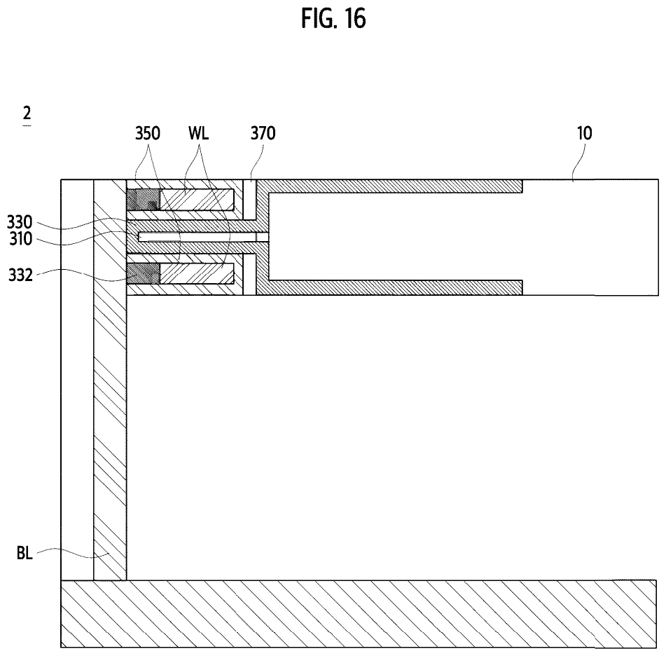

FIG. 15 schematically illustrates at least a portion of the memory device 2 according to at least one embodiment of the present disclosure. FIG. 16 schematically illustrates at least a portion of the memory device 2 according to at least one embodiment of the present disclosure.

In at least one example, the memory device 2 may include the substrate 300, an insulating layer 310, a channel layer 330, a gate insulating layer 350, a word line WL, a bit line BL, and a capacitor 10. In at least one example, the memory device 2 may have a vertical stacked structure. In at least one example, the vertical stacked structure may include a plurality of memory devices 2 arranged in three dimensions. In at least one example, at least some of the plurality of memory devices 2 may be stacked along the second direction D2. In at least one example, the vertical stacked structure may refer to a structure in which the channel layer 330 extends along a side surface of a word line WL and a surface extending in a direction away from a bit line BL. In at least one example, the plurality of memory devices 2 may be stacked along a stacking direction (e.g., the second direction D2), a gap may exist between adjacent memory devices 2, and an insulating film including an insulating material may be disposed between the gaps.

The capacitor 10 of FIGS. 15 and 16 may refer to the description of the capacitor 10 in FIGS. 1 to 13 rotated to extend in a horizontal direction (e.g. the first direction D1), unless otherwise contradictory.

In at least one example, each memory device 2 may be connected to one bit line BL and two word lines WL. In at least one example, the bit line BL may extend along the second direction D2. In at least one example, there may be a plurality of bit lines BL, and the plurality of bit lines BL may be arranged along the first direction D1. In at least one example, a plurality of bit lines BL may be arranged along the third direction D3. In at least one example, adjacent bit lines BL among the disposed bit lines BL may be insulated from each other by having an insulating film disposed between the bit lines.

In at least one example, the bit line BL may be electrically connected to the channel layer 330. The bit line BL may be in contact with the channel layer 330.

In at least one example, the word line WL may extend along the third direction D3. In at least one example, there may be a plurality of word lines WL, and the plurality of word lines WL may be arranged along the first direction D1 while being spaced apart from each other in the second direction D2.

In at least one example, a spacer 332 may be disposed between the word line WL and the bit line BL. In at least one example, the spacer 332 may include an insulating material and insulate the bit line BL and the word line WL from each other.

In at least one example, the gate insulating layer 350 may surround at least a portion of a surface of the word line WL. In at least one example, the gate insulating layer 350 may conformally surround the word line WL. In at least one example, the gate insulating layer 350 may surround at least a portion of each of upper, side, and lower surfaces of the word line WL. In at least one example, the gate insulating layer 350 may surround a surface of the spacer 332. In at least one example, the gate insulating layer 350 may surround at least a portion of each of upper and lower surfaces of the spacer 332.

In at least one example, the gate insulating layer 350 may be connected to the bit line BL. In at least one example, a portion of the gate insulating layer 350 covering the upper surface of the spacer 332 and a portion of the gate insulating layer 350 covering the lower surface of the spacer 332 may be connected to the bit line BL.

In at least one example, in the channel layers 330 arranged in the second direction D2, an interlayer insulating film (not illustrated) including an insulating material may be disposed in the gap between adjacent channel layers 330 with respect to the second direction D2.

In at least one example, the channel layer 330 may be disposed between facing surfaces of two adjacent word lines WL in the second direction D2. In at least one example, the channel layer 330 may be separated from the word lines WL by two gate insulating layers 350.

In at least one example, the channel layer 330 may be connected to the bit line BL between two adjacent word lines WL in the second direction D2. In at least one example, a region of the channel layer 330 surrounding at least a portion of the two gate insulating layers 350 may be connected by a region of the channel layer 330 surrounding at least a portion of a side surface of the bit line BL. In at least one example, the channel layer 330 may conformally surround one surface of the gate insulating layer 350 and the side surface of the bit line BL.

In at least one example, the insulating layer 310 may be disposed between regions of the channel layer 330 surrounding one surface of two gate insulating layers 350. In at least one example, the gate insulating layer 350, the channel layer 330, the insulating layer 350, the channel layer 330 and the gate insulating layer 350 may be sequentially disposed between two adjacent word lines WL in a cross-section cut in the second direction D2. In at least one example, the channel layer 330 may be disposed between the insulating layer 310 and the bit line BL in a cross-section cut in the first direction D1.

In at least one example, the channel layer 330 may be separated from a side surface of the word line WL by the gate insulating layer 350 and the etch stop film 370.

In at least one example, the etch stop film 370 may be positioned on one side of the word lines WL. The gate insulating layers 350 may be disposed between the etch stop film 370 and the word lines WL. In at least one example, the etch stop film 370 may surround at least a portion of a side surface of the gate insulating layer 350. In at least one example, the etch stop film 370 may extend in the second direction D2.

In at least one example, the channel layer 330 covers at least one surface of the gate insulating layer 350 and the etch stop film 370, and may extend over a side surface of the etch stop film 370. In at least one example, the channel layer 330 may surround the etch stop film 370 along the second direction D2.

In at least one example, the channel layer 330 may extend in the first direction D1 away from the bit line BL. In at least one example, the channel layer 330 may extend parallel to the substrate 300 along the surface of the capacitor 10. In at least one example, the channel layer 330 may be electrically connected to the capacitor 10.

Hereinafter, embodiments of the present application are further described with reference to specific examples. The examples are intended to illustrate the present application only and not to limit the scope of the appended claims. It will be apparent to those skilled in the art that various changes and modifications to the examples are possible within the scope and technical idea of the present application. Such variations and modifications should be included in the scope of the appended claims.

### Example 1

A lower electrode 110 including TiN was formed by deposition on a substrate structure 100, and a lower interface layer 210 including TiO as an oxide of one or more tetravalent atoms and TaO as an oxide of one or more pentavalent atoms was formed by deposition on the lower electrode 110. In this case, the lower interface layer 210 was manufactured by varying the content of Ta relative to the total number of elements excluding oxygen.

Then, a dielectric layer 130 was formed by depositing HZO, which is an amorphous ferroelectric, on the lower interface layer 210, and an upper electrode 120 was formed. Then, a capacitor 10 was manufactured by crystallizing the dielectric layer 130 through a heat treatment process. In this case, the thickness T₁ of the dielectric layer 130 was approximately 5.5 nm, and the thickness T₂ of the lower interface layer 210 was approximately 0.7 nm. The lower interface layer 210 and the dielectric layer 130 were formed using the atomic layer deposition (ALD) method.

### Example 2

A capacitor 10 was manufactured in the same manner as in Example 1, except that NbO was used as an oxide of one or more pentavalent atoms. In this case, the capacitor was manufactured with the content of Nb being 15 at % relative to the total number of elements excluding oxygen among the constituent elements of the lower interface layer 210.

### Comparative Example

A capacitor 10 was manufactured in the same manner as Example 1, except that the lower interface layer 210 was not formed.

### Evaluation Example 1

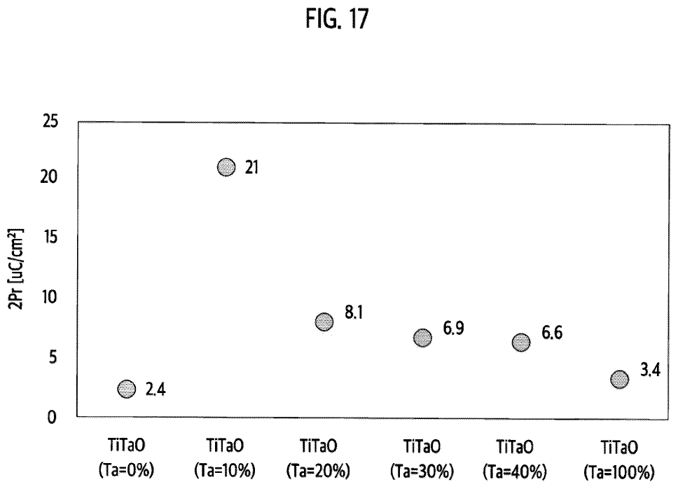

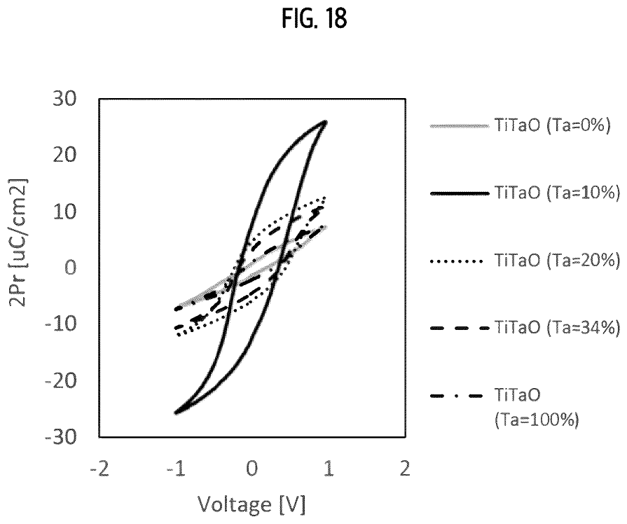

Pᵣ characteristics of the capacitor 10 of Example 1 were measured by varying the voltage applied to the upper electrode 120 of the capacitor 10. The voltage sweep was performed three times in the order of 0 V→1 V→−1 V→0 V between −1 V and 1 V, and the average value was calculated. The measurements were performed using the TF3000 analyzer and Summit12000 probe station. Measurement results for this are shown in FIGS. 17 and 18.

FIG. 17 shows a value of twice the size of the residual polarization (2Pᵣ) when the electric field applied is made 0 after a saturation polarization value of the dielectric layer 130 is reached for a capacitor 10 including a dielectric layer 130 in which the content of Ta relative to the total number of elements excluding oxygen among constituent elements of the lower interface layer 210 is varied from 0 at %, 10 at %, 20 at %, 30 at %, 40 at %, and 100 at %. The largest 2Pr value was confirmed in the capacitor 10 including the dielectric layer 130 with the Ta content of 10 at %. It was confirmed that 2Pr was approximately 8 or more when the Ta content was approximately 6 at % to 15 at %, and that 2Pr was approximately 8 or more when the Ta content was approximately 3 at % to 20 at %.

FIG. 18 shows a hysteresis loop of the dielectric layer 130 for the capacitor 10 including the dielectric layer 130 in which the Ta content is varied from 0 at %, 10 at %, 20 at %, 34 at %, and 100 at %. In the capacitor 10 including the dielectric layer 130 with the Ta content of 10 at %, the area and Pᵣ value of the largest closed loop could be confirmed. It was confirmed that as the Ta content approached 0 at % or the highest 100 at %, the area of the closed curve and the Pᵣ value tended to decrease.

In order for the polarization value to become 0, an electric field in the opposite direction may be applied, and the size of the electric field at this time is called the coercive field (E_{C}). When an additional electric field is applied in the opposite direction, the polarization value becomes saturated in a similar way to when the electric field was initially applied, and when an electric field is applied again in the original direction, a closed loop is formed when saturated polarization occurs. The hysteresis curve is very similar to that of ferromagnets and is the most representative characteristic of the ferroelectric.

### Evaluation Example 2

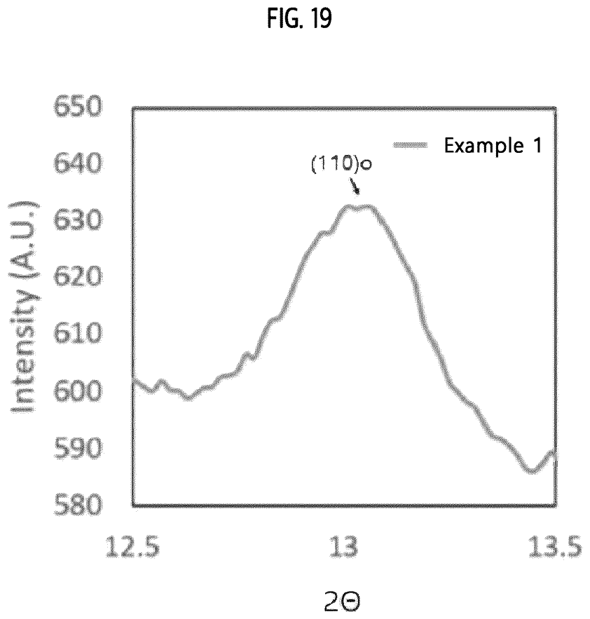

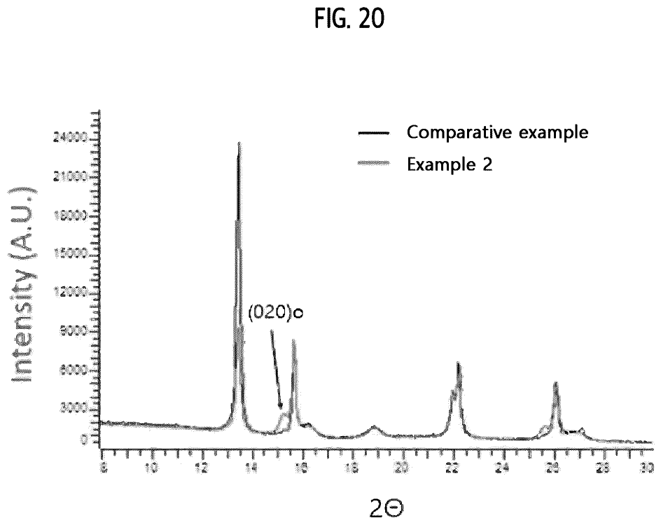

For the dielectric layer 130 of the capacitor 10 manufactured in Example 1, an x-ray diffraction (XRD) spectrum graph was obtained in a vertical direction of the interface between the lower interface layer 210 and the dielectric layer 130 through the XRD analysis method, and is shown in FIG. 19 (2Θ range: 12.5 degrees to 13.5 degrees). In addition, for the dielectric layer 130 of each of the capacitors 10 manufactured in Example 2 (red) and Comparative Example (black), an XRD spectrum graph was obtained in the vertical direction of the interface between the lower interface layer 210 and the dielectric layer 130 through the XRD analysis method, and is shown in FIG. 20 (2Θ range: 8 degrees to 30 degrees). In the XRD analysis method, measurements were performed using grazing incidence XRD using high-energy XRD (incident angle: 0.5 degrees).

Referring to FIG. 19, a peak appears when 2Θ is approximately 13 degrees, and through the appearance of the peak, it may be seen that the dielectric layer 130 according to Example 1 includes a crystal structure of the orthorhombic crystal system having a predominate orientation of (110)o with respect to the vertical direction of the interface between the lower interface layer 210 and the dielectric layer 130.

Referring to FIG. 20, a peak of 2Θ appears in a range of approximately 15 degrees to 15.5 degrees, and through the appearance of the peak, it may be seen that the dielectric layer 130 according to Example 2 includes a crystal structure of the orthorhombic crystal system having a predominate orientation of (020)o with respect to the vertical direction of the interface between the lower interface layer 210 and the dielectric layer 130. On the other hand, the dielectric layer 130 according to the comparative example did not show a peak in the range of 2Θ of approximately 15 degrees to 15.5 degrees.

The present disclosure may provide a memory device having excellent remnant polarization (Pᵣ) characteristics of a ferroelectric while minimizing its size.

Effects of the present disclosure are not limited to those mentioned above, and other effects not mentioned will be clearly understood by those skilled in the art from the description below.

In the above, the example embodiments of the present disclosure have been described with reference to the accompanying drawings, but, the present disclosure is not limited to the example embodiments and may be manufactured in various different forms and those of ordinary skill in the art to which the present disclosure pertains may understand that the additional or alternative exemplary embodiments may be embodied in other specific forms without departing from the technical spirit or essential features of the present disclosure. Therefore, it is to be appreciated that the example embodiments described above are intended to be illustrative in all respects and not restrictive.

What is claimed is:

1. A capacitor comprising:
a lower electrode;
an upper electrode;
a dielectric layer insulating the lower electrode from the upper electrode, the dielectric layer including a ferroelectric; and
a lower interface layer between the lower electrode and the dielectric layer, the lower interface layer including an oxide of one or more tetravalent atoms and an oxide of one or more pentavalent atoms and a content of the pentavalent atoms relative to a total number of elements excluding oxygen among constituent elements of the lower interface layer is in a range of 3 atomic percent (at %) to 20 at %.

2. The capacitor of claim 1, wherein the one or more tetravalent atoms is one or more of titanium (Ti), zirconium (Zr), hafnium (Hf), silicon (Si), germanium (Ge), or tin (Sn).

3. The capacitor of claim 1, wherein the one or more pentavalent atoms is one or more of tantalum (Ta), niobium (Nb), or vanadium (V).

4. The capacitor of claim 1, wherein a thickness of the lower interface layer is 2 nanometers (nm) or less.

5. The capacitor of claim 1, wherein a thickness of the dielectric layer is 7 nanometers (nm) or less.

6. The capacitor of claim 1, further comprising:
an upper interface layer between the upper electrode and the dielectric layer.

7. The capacitor of claim 6, wherein the upper interface layer includes a second oxide of one or more tetravalent atoms and a second oxide of one or more pentavalent atoms.

8. The capacitor of claim 6, wherein the content of the one or more pentavalent atoms relative to the total number of elements excluding oxygen among constituent elements of the upper interface layer is in a range of 3 at % to 20 at %.

9. The capacitor of claim 1, wherein the upper electrode and the lower electrode each independently include one or more of titanium nitride, niobium nitride, or molybdenum nitride.

10. The capacitor of claim 1, wherein the ferroelectric includes a ferroelectric phase and one or more of hafnium (Hf) or zirconium (Zr).

11. The capacitor of claim 1, further comprising:
an oxide layer between the lower interface layer and the lower electrode.

12. The capacitor of claim 1, wherein the lower electrode includes a first lower electrode and a second lower electrode, and
the capacitor further comprises a supporter connected between the first lower electrode and the second lower electrode.

13. The capacitor of claim 12, wherein the lower interface layer includes titanium oxide as the oxide of the one or more tetravalent atoms and tantalum oxide as the oxide of the one or more pentavalent atoms.

14. A memory device comprising:
at least one of the capacitor of claim 1; and
one or more transistors electrically connected to the at least one capacitor.

15. A capacitor comprising:
a lower electrode;
an upper electrode;
a dielectric layer insulating the lower electrode from the upper electrode, the dielectric layer including a ferroelectric and a crystal structure having an orthorhombic crystal system; and
a lower interface layer between the lower electrode and the dielectric layer, the lower interface layer including an oxide of one or more tetravalent atoms and an oxide of one or more pentavalent atoms,
wherein the crystal structure having the orthorhombic crystal system has a predominate orientation of (110)o or (020)o with respect to an in-plane direction of an interface between the lower interface layer and the dielectric layer.

16. The capacitor of claim 15, wherein the dielectric layer includes at least one of
the crystal structure having the orthorhombic crystal system with the predominate orientation of (110)o and the one or more pentavalent atoms includes tantalum (Ta), or
the crystal structure having the orthorhombic crystal system with the predominate orientation of (020)o and the one or more pentavalent atoms includes niobium (Nb).

17. The capacitor of claim 15, wherein the ferroelectric includes one or more of hafnium (Hf) or zirconium (Zr).

18. The capacitor of claim 15, further comprising:
an upper interface layer between the upper electrode and the dielectric layer.

19. The capacitor of claim 18, wherein the upper interface layer includes a second oxide of one or more tetravalent atoms and a second oxide of one or more pentavalent atoms.

20. The capacitor of claim 18, wherein a content of the one or more pentavalent atoms relative to a total number of elements excluding oxygen among constituent elements of the upper interface layer is in a range of 3 atomic percent (at %) to 20 at %.
